(19) United States
(12) Patent Application Publication
(10) Pub. No.: US 2003/0155907 A1
(43) Pub. Date: Aug. 21, 2003

(54) Test method and test device for integrated circuits

(75) Inventors: Johnson Hsu, Hsinchu (TW); San-Pen Lin, Hsinchu (TW); Chin-Hoe Tan, Hsinchu (TW); Huan-Ping Su, Hsinchu (TW); Auger Horng, Hsinchu (TW); Hsien-Ta Chiu, Hsinchu (TW)

Correspondence Address: EDWARDS & ANGELL, LLP, P.O. BOX 9169, BOSTON, MA, 02209, US

(73) Assignee: UltraTera Corporation, Taiwan, R.O.C.

(21) Appl. No.: 10/144,642

(22) Filed: May 13, 2002

(30) Foreign Application Priority Data
Feb. 19, 2002 (TW) 90103697

(51) Int. Cl. G01R 1/00

(52) U.S. Cl. 324/158.1

(57) ABSTRACT

A test method and a test device for integrated circuits are proposed. The test device includes: a test platform having a plurality of spaced-apart test tunnels; a test tray defined with board attach areas corresponding in position to the test tunnels, whereby a strip board having a plurality of semiconductor packages can be placed on a board attach area, and aligned with a corresponding test tunnel; and a control mechanism for gradually moving the test tray to perform tests for the semiconductor packages on the strip board. In operation of the test method, first, a plurality of strip boards having semiconductor packages are placed on the test tray, and each corresponds to a test tunnel of the test platform. Then, the test tray is gradually moved in a manner as to perform tests for all semiconductor packages on the strip board step by step.

### FIELD OF THE INVENTION

The present invention relates to methods and devices for testing semiconductor packages, and more particularly, to a test device having a plurality of test tunnels, allowing a plurality of integrated circuits to be simultaneously tested by the test device, and a test method of using the test device for performing tests for the semiconductor packages.

### BACKGROUND OF THE INVENTION

With integrated (IC) technology developing toward high integration, a variety of semiconductor package structures with increased input/output (I/O) ports are generated in order to reduce pitch spacing between adjacent I/O ports and to miniaturize overall structural profile. It is therefore critical in the art to efficiently, quickly, easily and precisely test semiconductor package of fabricated semiconductor packages.

A conventional method for testing packaged integral circuits, is to first cut a wafer into multiple single chips, and then place the chips in order on a chip-carrier (such as substrate or leadframe) strip. After performing wire-bonding and molding processes, the packaged structure is singulated into individual semiconductor packages. Fabricated semiconductor packages are assigned to various test fixtures corresponding to package sizes through the use of a classifying machine, and then transferred to a test device where tests are performed for the semiconductor packages.

For example, a chip scale package (CSP), a mainstream of highly integrated IC products, is preferably favored for its low profile or volume. During fabrication processes thereof, a plurality of chips formed by cutting through a wafer are in turn placed and array-arranged on a substrate strip. Then, after completing wire-bonding and molding processes, the packaged structure is singulated to form a plurality of individual semiconductor packages (CSPs). Fabricated CSPs are transferred by a classifying machine to be accommodated by specially-designed test fixtures, and subject to tests in a test platform. However, same functioning integrated circuits or semiconductor packages from different manufacturers would have significant size or dimension deviation or variation; thereby, it needs to prepare various types of test fixtures for use with differently sized packages, making costs for test performance greatly increased. A solution to the cost-increase problem is the disclosure of a test strip board that is currently well adopted in the art.

FIG. 1 illustrates a conventional test device for semiconductor packages. As shown in the drawing, first, a strip board 2 mounted with a plurality of integrated circuits 20, is placed on a test tray 12; then, the test tray 12 is transferred to a test platform 10′, where the integrated circuits 20 on the strip board 2 are electrically connected to corresponding test interfaces 110 of the test platform 10′, and performed with various tests. Subsequently, the test tray 12 is operated to move in a manner as to allow each of the integrated circuits 20 on the strip board 2 to be in sequence subject to the tests. Therefore, all strip boards in a classifying machine are tested by the same set of test interfaces 110 of the test device.

The conventional test device is formed with a plurality of test interfaces 110, allowing a plurality of semiconductor packages 20 on the strip board 2 to be simultaneously tested. However, when a test interface 110 of the test platform 10′ operates with test errors or inaccuracy, other strip boards that have been tested need to be re-tested, thereby undesirably reducing test efficiency. Moreover, when a test interface 110 malfunctions, the test device needs to entirely stop operation, making operationality and yield of the test device both reduced.

Furthermore, a conventional test interface 110 is formed with a plurality of test pins or terminals to come into contact with I/O ports (not shown) of an semiconductor package 20 for test performance. Such a test pin can be of a Y shape, a side contact, a probe, a protrusion, an elastic head, etc. FIG. 2 illustrates a semiconductor package 20 accommodated on a test interface 110. As shown in the drawing, test pins 1100 of the test interface 110 are Y-shaped, and the semiconductor package 20 is a BGA (ball grid array) package. In response to low profile, high integration and improved performances of integrated circuits, test pins 1100 of the test interface 110 are preferably increased in number correspondingly to densely-arranged I/O ports of the semiconductor package 20. However, with test pins 1100 of the test interface 110 being in contact with respective solder balls 200 of the integrated circuit 20, as integrated circuits 20 provided with many solder balls 200 are closely spaced on the strip board 2, test interfaces 110 and test pins 1100 are correspondingly densely arranged in position, making high frequency interference easily generated between adjacent test interfaces 110; this would undesirably reduce test reliability. In addition, by long-term using the test interfaces 110, test pins 1100 are easily damaged in structure; however, due to high-density arrangement of test pins 1100, maintenance and repair for damaged test pins 1100 are hardly implemented, and densely-arranged test pins 1100 need to be more precisely fabricated, thereby undesirably increasing production costs thereof.

### SUMMARY OF THE INVENTION

An objective of the present invention is to provide a test method for semiconductor packages applied to a test device having a plurality of test tunnels, whereby when a test tunnel malfunctions, strip boards on a test tray can still be tested through the use of other test tunnels of the test device, thereby greatly enhancing operationality and yield of the test device; and, when a test tunnel operates with test errors or inaccuracy, it only needs to re-perform tests for a corresponding strip board that is being tested by the test tunnel, without having to retest other strip boards on the test tray, thereby effectively improving test efficiency of the test device.

Another objective of the invention is to provide a test device for semiconductor packages, which can be easily fabricated and maintained with high reliability.

In accordance with the above and other objectives, the present invention proposes a test method and a test device for semiconductor packages. The test device comprises: a test platform having a plurality of test tunnels that are properly spaced apart from each other, a test tray formed with a plurality of board attach areas, wherein each of the board attach areas accommodates a strip board having a plurality of semiconductor packages, and corresponds in position to a test tunnel of the test platform, allowing the strip board mounted on the board attach area to be aligned with the corresponding test tunnel; and a control mechanism for gradually moving the test tray in a manner that, a predetermined number of semiconductor packages on the strip board are adapted to be electrically connected to the corresponding test tunnel, so as to perform tests for the semiconductor packages on the strip board step by step. The test device further comprises a classifying device for placing a plurality of strip boards on the test tray. And, the control mechanism comprises a server for moving the test tray at a vertical direction and in a gradual manner, and a programmable controller for controlling the server.

The test method for semiconductor packages of the invention is applied to a test device having a plurality of test tunnels that are properly spaced apart from each other. The test method comprises the steps of: (1) placing a plurality of strip boards on a test tray of the test device, wherein each of the strip boards has a plurality of semiconductor packages, and corresponds in position to a test tunnel of the test device; and (2) electrically connecting a predetermined number of semiconductor packages formed on a strip board to a corresponding test tunnel, and gradually moving the test tray to perform tests for the integrated circuits of the strip board step by step.

A plurality of equally-sized strip boards can be array-arranged on the test tray. Integrated circuits mounted on the same strip board are tested by using a particular test tunnel of the test platform, and a plurality of test tunnels formed on the test platform respectively correspond to the strip boards on the test tray, for simultaneously performing tests for the strip boards. Furthermore, in response to differently sized semiconductor packages, prior to the step (2), a programmable controller can be adopted to adjust moving distance of the test tray, without having to change dimensions of the test tray and a classifying device for placing strip boards on the test tray. In another embodiment, the programmable controller can also be used for adjusting moving distance of the test platform.

In the use of the test method and test device for integrated circuits of the invention, a plurality of strip boards can be simultaneously tested; during test processes, each of the strip boards is tested by using a corresponding test tunnel in a manner that, all semiconductor packages on the same strip board are performed with tests by test interfaces of the test tunnel. Therefore, when a test tunnel operates with test errors or inaccuracy, it only needs to re-perform tests for a corresponding strip board that is being tested by the test tunnel, without having to re-test other strip boards on the test tray, thereby effectively improving test efficiency of the test device. Moreover, when a test tunnel malfunctions, strip boards on the test tray can still be tested through the use of other test tunnels of the sane test device, thereby greatly enhancing operationality and yield of the test device.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a schematic diagram of a conventional test device for semiconductor packages;

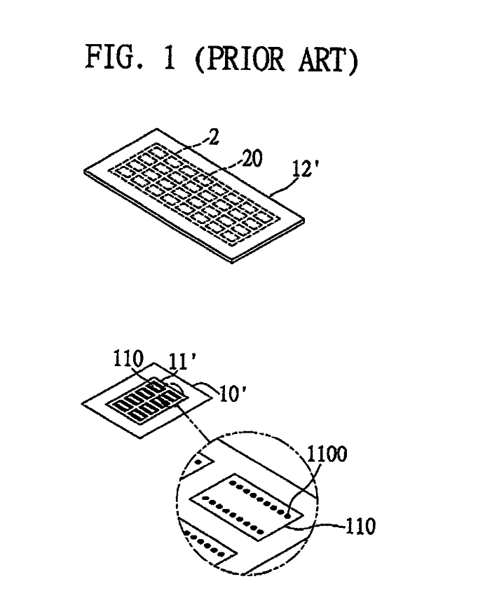

FIG. 2 (PRIOR ART) is a cross-sectional view showing partly the conventional test device of FIG. 1; and

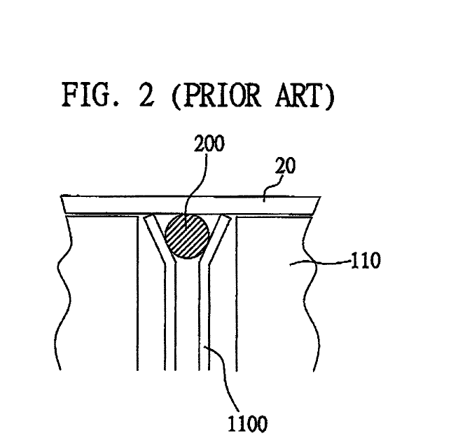

FIG. 3 is a schematic diagram of a test device for semiconductor packages of the invention.

### DETAILED DESCRIPTION OF THE PREFERRED EMBODIMENT

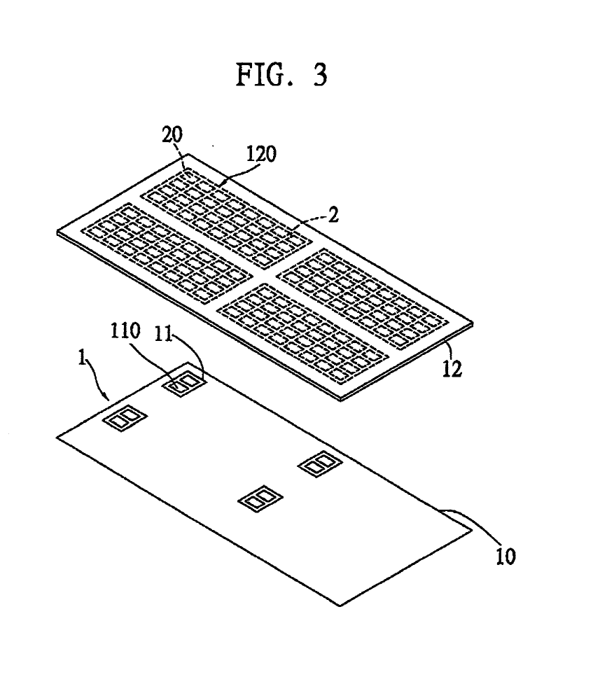

FIG. 3 illustrates a test device 1 for semiconductor packages of the present invention. As shown in the drawing, the test device 1 comprises a test platform 10, a test tray 12 and a control mechanism (not shown).

The test platform 10 is provided with a plurality of test tunnels 11 that are properly spaced apart from each other, and each has a plurality of test interfaces 110. The test tray 12 is formed with a plurality of board attach areas 120, wherein each of the board attach areas 120 is used to accommodate a strip board 2 mounted with a plurality of semiconductor packages 20, and corresponds in position to a test tunnel 11 of the test platform 10, whereby the strip board 2 disposed on the board attach area 120 is also aligned with the corresponding test tunnel 11, allowing the semiconductor packages 20 on the strip board 2 to be electrically connected to a plurality of test interfaces 110 of the test tunnel 11, such that tests can be performed for the semiconductor packages 20. The control mechanism is used to gradually move the test tray 12 in a manner that, a predetermined number of semiconductor packages 20 on a strip board 2 are adapted to come into electrical contact with a corresponding test tunnel 11, so as to perform tests for all the semiconductor packages 20 on the strip board 2 step by step.

The test device 1 further comprises a classifying machine (not shown) for placing strip boards 2 on the test tray 12, wherein the strip boards 2, each having a plurality of integrated circuits 20 thereon, are equally sized and array-arranged on the test tray 12. Such a strip board 2 can also be an uncut leadframe strip. Since the classifying machine is necessary equipment for use with a conventional test device, internal structure and functions thereof are not to be further described herein.

The control mechanism comprises a server (not shown) for moving the test tray 12 at a vertical direction and in a gradual manner; also, the test platform 10 can be moved at a vertical direction and in a gradual manner, so as to allow all semiconductor packages 20 mounted on a strip board 2 to be performed with tests step by step. Besides, the control mechanism further comprises a programmable controller for adjusting moving distance of the server. Thereby, moving distance of the test tray 12 can also be correspondingly modulated by the programmable controller in response to differently sized semiconductor packages 20, without having to change dimensions of the test tray 12 or the classifying machine.

Integrated circuits 20 mounted on a particular strip board 2 are all being tested through the same test tunnel 11 in a manner that, the test tunnel 11 tests at least an integrated circuit 20 at a time, and the control mechanism moves the test tray 12 (or the test platform 10) corresponding to locations and sizes of the semiconductor packages 20 on the strip board 2, allowing a predetermined number of the semiconductor packages 20 to be aligned in position to a plurality of test interfaces 110 on the test platform 10 and subject to tests, so as to complete testing of all the semiconductor packages 20 step by step. The test platform 10 is formed with a plurality of test tunnels 11 properly spaced apart from each other. For preventing high frequency interference, the number of test interfaces 110 in a test tunnel 11 can be reduced, such that when the plurality of test tunnels 11 operate simultaneously to perform high-frequency tests, it can eliminate the occurrence of signal interference caused by over-crowded arrangement and excess number of the test interfaces 110.

Moreover, when a test tunnel 11 improperly functions, the test platform 10 still keeps proceeding with tests, thereby effectively improving operationality and yield of the test device 1. Further, if a test tunnel 11 operates with test errors or inaccuracy, it only needs to re-perform tests for a strip board 2 that is being tested by the test tunnel 11, without adversely affecting or having to re-test strip boards that have been tested in the same classifying machine, thereby helping enhance test efficiency of the test device 1.

In addition, with integrated circuits 20 being array-arranged on a strip board 2, the test device 1 of the invention can also adopt a high frequency interface matrix (hi-fix) having a plurality of DUT (die under test) boards for use to test single semiconductor packages. By adjusting relative positions between the DUT boards of the Hi-fix and test tunnels, the number of semiconductor packages on a strip board to be simultaneously tested, and space arrangement for a test tray and a test platform, can be optimized.

The test method of the invention for use with semiconductor package mounted on a strip board, is applied to the test device l having a plurality of test tunnels 11 properly spaced apart from each other. First, a classifying machine is used to place and array-arrange a plurality of strip boards 2 on corresponding board attach areas 120 of a test tray 12 of the test device 1, wherein each strip board 2 is mowed with a plurality of equally-sized semiconductor packages 20. Next, the strip boards 2 are adapted to be aligned with corresponding test tunnels 11 of the test platform 10. Then, a predetermined number of semiconductor packages 20 on each strip board 2 are urged to be electrically connected to the same number of test interfaces 110 of a corresponding test tunnel 11. Subsequently, tests are performed for simultaneously testing the predetermined number of semiconductor packages 20 on the strip board 2. Finally, a server of a control mechanism of the test device 1 operates to move the test tray 12 (or the test platform 10) gradually according to locations of semiconductor packages 20 (that are to be tested) on the strip board 2, so as to complete testing of all semiconductor packages 20 on the strip board 2 step by step.

In response to differently sized semiconductor packages 20, a programmable controller can be employed to adjust moving distance of the test tray 12 (or the test platform 10), without having to change the test tray 12 and the classifying machine.

The invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

What is claimed is:

1. A test method for integrated circuits, applied to a test device having a plurality of test tunnels that are properly spaced apart from each other; the test method comprising the steps of:
placing a plurality of strip boards on a test tray of the test device, wherein each of the strip boards is formed with a plurality of semiconductor package, and corresponds in position to a test tunnel of the test device; and
electrically connecting a predetermined number of semiconductor package formed on the strip board to a corresponding test tunnel, and moving the test tray to perform tests for the semiconductor package of the strip board step by step.

2. The test method of claim 1, wherein the strip board is either one of an uncut leadframe strip and a substrate strip.

3. A test device for integrated circuits, comprising:
a test platform having a plurality of test tunnels that are properly spaced apart from each other;
a test tray formed with a plurality of board attach areas, wherein each of the board attach areas accommodates a strip board formed with a plurality of semiconductor package, and corresponds in position to a test tunnel of the test platform, allowing the strip board mounted on the board attach area to be aligned with the corresponding test tunnel; and
a control mechanism for moving the test tray in a manner that, a predetermined number of semiconductor package on the strip board are adapted to be electrically connected to the corresponding test tunnel, so as to perform tests for the semiconductor package on the strip board step by step.

4. The test device of claim 3, wherein the test tunnel has a plurality of test interfaces provided in a number equal to the predetermined number of the semiconductor package.

5. The test device of claim 4, wherein the test tunnel is provided with a high frequency interface matrix (hi-fix) having a plurality of DUT (die under test) boards for use to testing a single semiconductor package.

6. The test device of claim 3, further comprising a classifying machine for placing a plurality of strip boards on the test tray.

7. The test device of claim 3, wherein the control mechanism comprises a server for moving the test tray at a vertical direction and in a gradual manner, and a programmable controller for controlling the server.
